(19) United States
(12) Patent Application Publication
(10) Pub. No.: US 2024/0174440 A1
(43) Pub. Date: May 30, 2024

(54) SUBSTRATE TRANSFERRING APPARATUS AND SUBSTRATE TRANSFERRING METHOD

(71) Applicant: SEMES CO., LTD., Cheonan-si (KR)

(72) Inventors: Kisub YOON, Suwon-si (KR); Jiyoon JUNG, Ansan-si (KR)

(73) Assignee: SEMES CO., LTD., Cheonan-si (KR)

(21) Appl. No.: 18/494,055

(22) Filed: Oct. 25, 2023

(30) Foreign Application Priority Data
Nov. 30, 2022 (KR) 10-2022-0165102

(51) Int. Cl. B65G 1/04; B61L 3/00

(52) U.S. Cl. CPC B65G 1/0457; B61L 3/008; B65G 2201/0297

(57) ABSTRACT

A substrate transfer apparatus includes a traveling rail including a straight section and a curved section, a raceway structure disposed on the traveling rail and configured to fix the traveling rail, a traveling device including a traveling wheel configured to travel on the traveling rail so as to transfer a substrate, a first sensor connected to the raceway structure and configured to recognize the traveling device, at least one second sensor connected to the raceway structure and configured to recognize the traveling device, and a third sensor connected to the traveling rail and configured to recognize the traveling device, wherein the at least one second sensor and the third sensor are configured to move in a traveling direction of the traveling device.

### CROSS-REFERENCE TO RELATED APPLICATION

This application is based on and claims priority under 35 U.S.C. § 119 to Korean Patent Application No. 10-2022-0165102, filed on Nov. 30, 2022, in the Korean Intellectual Property Office, the disclosure of which is incorporated by reference herein in its entirety.

### BACKGROUND

### 1. Field

The disclosure relates to a substrate transfer apparatus and a substrate transfer method. More specifically, the disclosure relates to a ceiling traveling substrate transfer apparatus.

### 2. Description of the Related Art

A semiconductor device may be manufactured by performing various manufacturing processes such as etching, deposition, and cleaning on a substrate. In a process of manufacturing the semiconductor device, the various manufacturing processes may be performed on the substrate within different process facilities.

Accordingly, the substrate on which the various manufacturing processes are performed may be accommodated in a carrier capable of accommodating a plurality of substrates and transferred between respective process facilities by a substrate transfer apparatus such as an overhead hoist transport (OHT).

### SUMMARY

Provided are a substrate transfer apparatus and a substrate transfer method capable of improving the productivity of a process of manufacturing a semiconductor device.

Additional aspects will be set forth in part in the description which follows and, in part, will be apparent from the description, or may be learned by practice of the presented embodiments of the disclosure.

According to an aspect of the disclosure, a substrate transfer apparatus includes a traveling rail including a straight section and a curved section, a raceway structure disposed on the traveling rail and configured to fix the traveling rail, a traveling device including a traveling wheel configured to travel on the traveling rail so as to transfer a substrate, a first sensor connected to the raceway structure and configured to recognize the traveling device, at least one second sensor connected to the raceway structure and configured to recognize the traveling device, and a third sensor connected to the traveling rail and configured to recognize the traveling device, wherein the at least one second sensor and the third sensor are configured to move in a traveling direction of the traveling device.

The at least one second sensor and the third sensor may be configured to move at the same speed as a traveling speed of the traveling device.

The first sensor may be configured to recognize a time when the traveling device enters the traveling rail.

The at least one second sensor may be configured to measure a diameter of the traveling wheel.

The third sensor may be configured to identify identification information of the traveling device.

In the traveling direction, the first sensor may be disposed relatively adjacent to the traveling device, and the at least one second sensor may be disposed relatively far from the traveling device.

The at least one second sensor may include two second sensors, and the two second sensors may be disposed to face each other with respect to a direction perpendicular to the traveling direction in the raceway structure.

The at least one second sensor may be a camera or a displacement sensor, and the third sensor may be a camera.

The at least one second sensor and the third sensor may be configured to move at the same time.

The third sensor may be disposed in the straight section of the traveling rail, and the first sensor and the at least one second sensor may be disposed in the raceway structure corresponding to the straight section of the traveling rail.

The substrate transfer apparatus may further include a control device configured to control operations of the first sensor, the at least one second sensor, and the third sensor.

According to another aspect of the disclosure, a substrate transfer apparatus includes a traveling rail including a straight section and a curved section, a raceway structure disposed on the traveling rail and configured to fix the traveling rail, a traveling device including a traveling wheel configured to travel on the traveling rail so as to transfer a substrate, a first sensor connected to the raceway structure and configured to recognize the traveling device, at least one second front sensor connected to the raceway structure and configured to recognize the traveling device, at least one second rear sensor connected to the raceway structure to be spaced apart from the at least one second front sensor in a traveling direction of the traveling device and configured to recognize the traveling device, and a third sensor connected to the traveling rail and configured to recognize the traveling device, wherein the at least one second front sensor, the at least one second rear sensor, and the third sensor are configured to move in the traveling direction.

The first sensor may be disposed between the at least one second front sensor and the at least one second rear sensor in the traveling direction.

The at least one second front sensor, the at least one second rear sensor, and the third sensor may be configured to move at the same speed as a traveling speed of the traveling device.

The at least one second front sensor and the at least one second rear sensor may be configured to measure a diameter of the traveling wheel.

The third sensor may be configured to identify identification information of the traveling device.

The at least one second front sensor, the at least one second rear sensor, and the third sensor may be configured to move at the same time.

The third sensor may be disposed in the straight section of the traveling rail, and the first sensor, the at least one second front sensor, and the at least one second rear sensor may be disposed in the raceway structure corresponding to the straight section of the traveling rail.

According to another aspect of the disclosure, a substrate transfer method includes recognizing a time when a traveling device in which a substrate is accommodated enters a traveling rail through a first sensor, moving a second sensor and a third sensor in a traveling direction of the traveling device when entry of the traveling device is recognized, and measuring a diameter of a traveling wheel of the traveling device through the second sensor while the second sensor is moving, and identifying identification information of the traveling device through the third sensor while the third sensor is moving.

The second sensor and the third sensor may move at the same speed as a traveling speed of the traveling device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a conceptual diagram schematically illustrating an overall configuration of a substrate transfer apparatus according to some embodiments;

FIG. 2A is a cross-sectional view illustrating a substrate transfer apparatus according to some embodiments; FIGS. 2B and 2C are plan views illustrating a substrate transfer apparatus according to an embodiment;

FIG. 3A is a cross-sectional view illustrating a substrate transfer apparatus according to an embodiment; FIG. 3B is a top plan view illustrating a substrate transfer apparatus according to an embodiment;

FIG. 4A is a cross-sectional view for explaining an operating method of a substrate transfer apparatus according to an embodiment; FIGS. 4B and 4C are plan views for explaining an operating method of a substrate transfer apparatus according to an embodiment;

FIG. 5A is a cross-sectional view for explaining an operating method of a substrate transfer apparatus according to an embodiment; FIGS. 5B and 5C are plan views illustrating an operating method of a substrate transfer apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The same reference numerals are used for the same components in the drawings, and redundant descriptions thereof will be omitted.

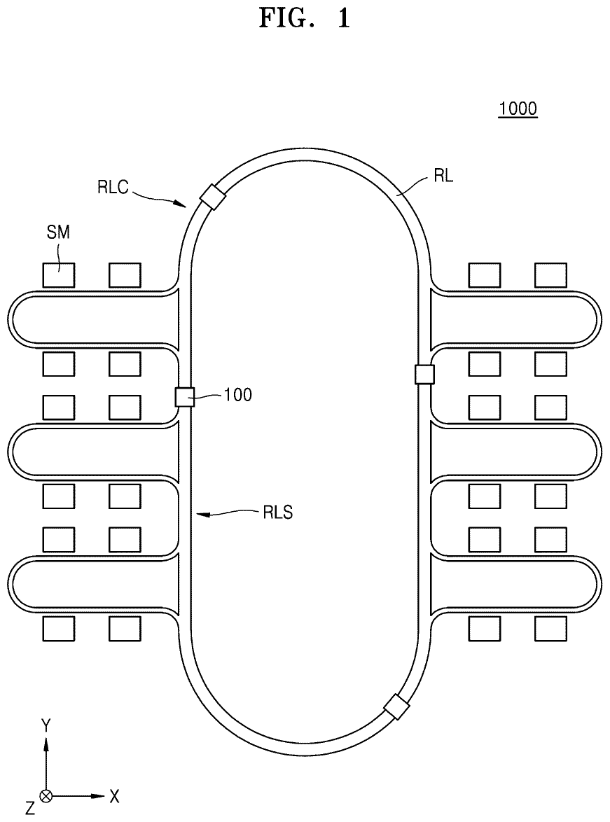

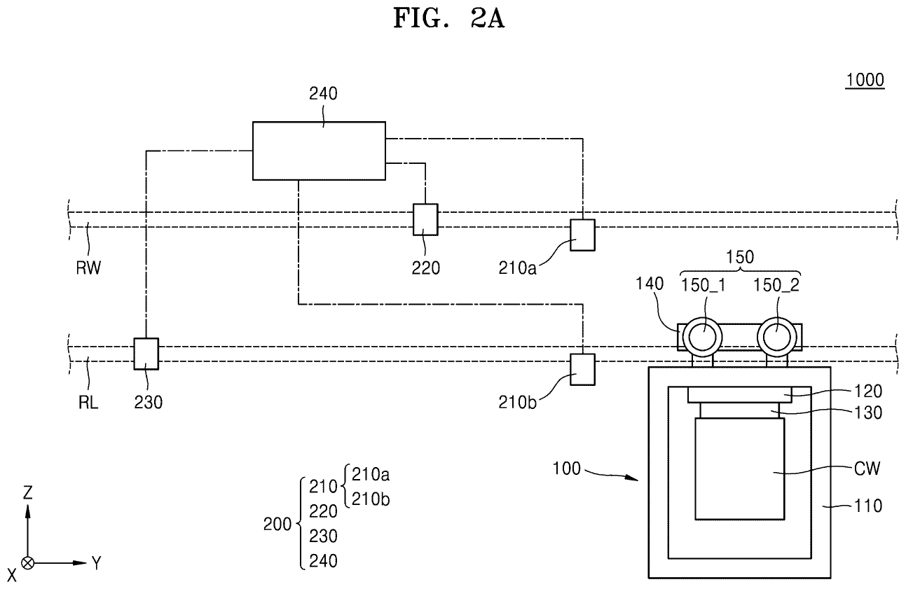

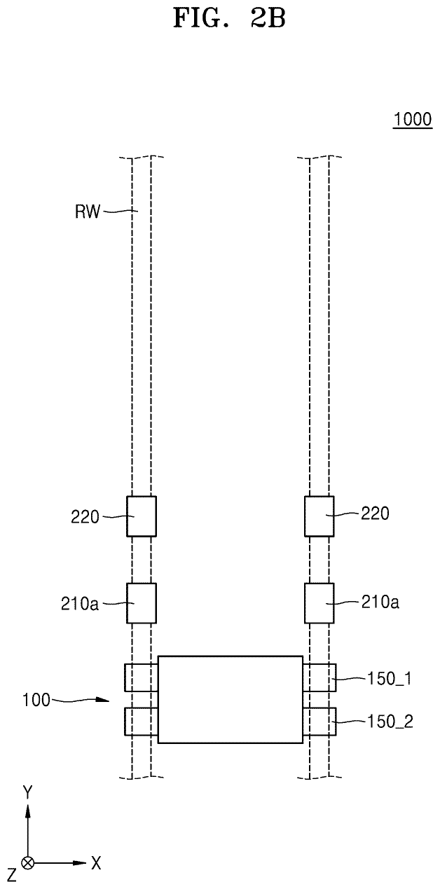

FIG. 1 is a conceptual diagram schematically illustrating an overall configuration of a substrate transfer apparatus 1000 according to some embodiments.

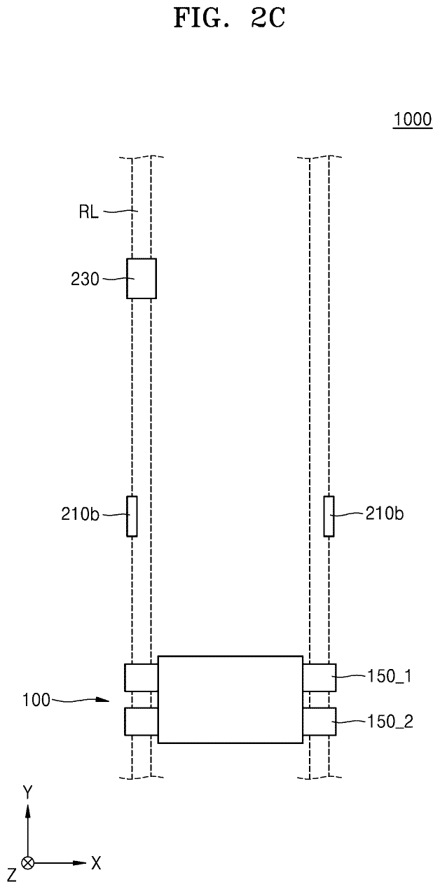

FIG. 2A is a cross-sectional view illustrating the substrate transfer apparatus 1000 according to some embodiments.

FIGS. 2B and 2C are plan views illustrating the substrate transfer apparatus 1000 according to an embodiment. Specifically, FIG. 2B is a plan view of the substrate transfer apparatus 1000 in which a traveling rail RL is omitted, and FIG. 2C is a plan view of the substrate transfer apparatus 1000 in which a raceway structure RW is omitted.

Referring to FIGS. 1 and 2A to 2C, the substrate transfer apparatus 1000 may include a traveling device 100, the traveling rail RL, the raceway structure RW, and a sensor device 200.

The traveling device 100 may be an overhead hoist transfer (OHT) that transfers a substrate on which a semiconductor manufacturing process is performed. Substrates in a substrate accommodation container CW may be respectively loaded to and unloaded from a plurality of semiconductor manufacturing facilities SM, by the traveling device 100. The traveling device 100 may include a housing 110, a container moving device 120, a container fixing device 130, a wheel body 140, and traveling wheels 150.

The substrate accommodation container CW may be accommodated in the housing 110. One surface of the housing 110 may be opened and closed to load or unload the substrate accommodation container CW to or from the housing 110. For example, one surface of the housing 110 is opened, and thus, the substrate accommodation container CW accommodated inside the housing 110 may move in a horizontal direction and be unloaded from the housing 110. The substrate accommodation container CW may accommodate a plurality of substrates. The substrate accommodation container CW may be, for example, a Front Opening Unified Pod (FOUP).

The container moving device 120 may be disposed on an upper surface inside the housing 110. The container moving device 120 may be moved in a horizontal direction or in a vertical direction within the housing 110.

The container fixing device 130 may be disposed on a lower surface of the container moving device 120. The substrate accommodation container CW may be attached to a lower surface of the container fixing device 130. Through this, the substrate accommodation container CW may be fixed inside the housing 110. When the container moving device 120 moves in a horizontal direction or in a vertical direction, the container fixing device 130 and the substrate accommodation container CW fixed by the container fixing device 130 may also move in the horizontal direction or in the vertical direction. Through this, the substrate accommodation container CW may be unloaded from the housing 110 or the substrate accommodation container CW may be loaded in the housing 110 from the outside.

The wheel body 140 may be disposed on an outer upper surface of the housing 110. The wheel body 140 may include an actuator configured to rotate the traveling wheel 150. In addition, the wheel body 140 may further include a steering wheel (not shown) configured to move the wheel body 140 in a direction perpendicular to a traveling direction of the wheel body 140.

The traveling wheels 150 may be provided on both sides of the wheel body 140. Each of traveling wheels 150 may include two front traveling wheels 150_1 and two rear traveling wheels 150_2. Here, the front traveling wheel 150_1 means the traveling wheel 150 relatively adjacent to a traveling direction of the traveling device 100 among the traveling wheels 150, and the rear traveling wheel 150_2 means the traveling wheel 150 relatively far from the traveling direction of the traveling device 100 among the traveling wheels 150. The two front traveling wheels 150_1 may be respectively provided to align in an X direction on both sides of the wheel body 140, and the two rear traveling wheels 150_2 may be respectively spaced apart from the two front traveling wheels 150_1 in the X direction on both sides of the wheel body 140. As the traveling wheel 150 rotates on the traveling rail RL, the traveling device 100 may travel along the traveling rail RL.

The traveling rail RL may include two rails. The traveling rail RL may include a straight section RLS and a curved section RLC. Here, the straight section RLS refers to a region in which the traveling rail RL extends in parallel with a specific direction (e.g., X direction), and the curved section RLC refers to a region in which the traveling rail RL extends along a circumference. The traveling device 100 may travel relatively quickly in the straight section RLS of the traveling rail RL and travel relatively slowly in the curved section RLC of the traveling rail RL.

The raceway structure RW may be disposed on the traveling rail RL, and may fix the traveling rail RL. The raceway structure RW may align with the traveling rail RL in the vertical direction (i.e., Z direction) and may extend along the traveling rail RL. Accordingly, the raceway structure RW may also include two structures extending along the two rails of the traveling rail RL.

The sensor device 200 may include a first sensor 210, second sensors 220, a third sensor 230, and a control device 240.

The first sensor 210 may be disposed relatively adjacent to the traveling device 100 in the traveling direction compared to the second sensors 220. The first sensor 210 may include first sub sensors 210a and second sub sensors 210b. The first sub sensor 210a may be connected to the raceway structure RW, and the second sub sensor 210b may be connected to the traveling rail RL. The first sub sensor 210a and the second sub sensor 210b may be disposed to overlap each other in the vertical direction (i.e. Z direction). The first sub sensor 210a and the second sub sensor 210b may measure a vertical length of an empty space between the raceway structure RW and the traveling rail RL. Based on this, the first sensor 210 may recognize a time when the traveling device 100 enters the traveling rail RL. Specifically, when the traveling device 100 enters the traveling rail RL, a part of the traveling device 100 is aligned with the first sub sensor 210a and the second sub sensor 210b in the vertical direction. Accordingly, the vertical length measured by the first sub sensor 210a and the second sub sensor 210b at the time when the traveling device 100 enters the traveling rail RL may be smaller than the vertical length at the time when the traveling device 100 does not enter the traveling rail RL. Through this, the first sensor 210 may recognize an entry time of the traveling device 100 and transmit information about the entry time to the control device 240.

The second sensors 220 may be connected to the raceway structure RW. Specifically, the two second sensors 220 may be disposed to face each other with respect to a direction (X direction) perpendicular to the traveling direction in the raceway structure RW. The second sensors 220 may be disposed relatively far from the traveling device 100 in the traveling direction compared to the first sensor 210. In an embodiment, the second sensors 220 may be sensors capable of measuring a diameter of the traveling wheel 150. In an embodiment, the second sensors 220 may be cameras or displacement sensors such as laser sensors. When the second sensors 220 are cameras, the second sensors 220 may measure the diameter of the traveling wheel 150 through an image obtained by capturing the traveling wheel 150. When the second sensors 220 are displacement sensors, the second sensors 220 may measure a distance between the raceway structure RW and an upper surface of the running wheel 150, compare the distance with a distance between the raceway structure RW and the traveling rail RL, and measure the diameter of the traveling wheel 150 through a difference value. The diameter of the traveling wheel 150 measured by the second sensors 220 may be transmitted to the control device 240. However, the disclosure is not limited thereto, and, for example, when the second sensors 220 are cameras, the second sensors 220 may measure other characteristics of the traveling device 100, for example, whether components of the traveling device 100 are well coupled to each other, through an image obtained by capturing the traveling device 100.

The third sensor 230 may be connected to the traveling rail RL. Specifically, the third sensor 230 may be disposed on only one side of the traveling rail RL. However, the disclosure is not limited thereto, and the two third sensors 230 may be disposed to face each other in a direction (X direction) perpendicular to the traveling direction on the traveling rail RL. The third sensor 230 may be disposed relatively far from the traveling device 100 in the traveling direction compared to the first sensor 210 and the second sensors 220. In an embodiment, the third sensor 230 may be a sensor capable of identifying identification information of the traveling device 100. Hereinafter, the identification information refers to information individually given to each of a plurality of traveling devices 100 included in the substrate transfer apparatus 1000 as shown in FIG. 1 in order to distinguish each of the plurality of traveling devices 100. In an embodiment, the third sensor 230 may be a camera. In this case, the third sensor 230 may identify the identification information of the traveling device 100 through an image obtained by capturing identification information displayed in front of the traveling device 100. The identification information of the traveling device 100 measured by the third sensor 230 may be transmitted to the control device 240.

In an embodiment, the second sensors and the third sensor 230 may move in the same direction as the traveling direction (Y direction) of the traveling device 100. Specifically, when the entry of the traveling device 100 is recognized by the first sensor 210, the second sensors 220 and the third sensor 230 may move together with the traveling device 100 in the same direction as the traveling direction (Y direction) of the traveling device 100.

In an embodiment, the second sensors 220 and the third sensor 230 may move at the same speed as the traveling device 100. Specifically, the third sensor 230 may move in the same direction as the traveling direction of the traveling device 100 at the same speed as the traveling speed of the traveling device 100. In this case, the third sensor 230 may move together with the traveling device 100 until the identification information of the traveling device 100 is identified, and may stop after the identification information of the traveling device 100 is identified.

In an embodiment, the second sensors 220 and the third sensor 230 may move at the same time. Specifically, the second sensors 220 and the third sensor 230 may be configured to move simultaneously at the time when the entry of the traveling device 100 is recognized by the first sensor 210.

In an embodiment, the second sub sensor 210b and the third sensor 230 may be disposed in the straight section RLS of the traveling rail RL, and the first sub sensor 210a and the second sensor 220 may be disposed in a part of the raceway structure RW corresponding to the straight section RLS of the traveling rail RL.

The control device 240 may control operations of the first sensor 210, the second sensors 220, and the third sensor 230. For example, the control device 240 may be configured to transmit and receive electrical signals to and from the first sensor 210, the second sensors 220, and the third sensor 230, and accordingly control the operations of the second sensors 220 and the third sensor 230.

The control device 240 may be implemented in hardware, firmware, software, or any combination thereof. For example, the control device 240 may be a computing device such as a workstation computer, a desktop computer, a laptop computer, or a tablet computer. For example, the control device 240 may include a memory device such as a read only memory (ROM) and a random access memory (RAM), and a processor configured to perform certain operations and algorithms, for example, a microprocessor, a central processing unit (CPU), a graphics processing unit (GPU), etc.

In the substrate transfer apparatus of the related art, sensors measuring a diameter of a traveling wheel of a traveling device were fixed. Accordingly, in order to measure the diameter of the traveling wheel of the traveling device that is traveling, there is a problem in that a traveling speed of the traveling device needs to be reduced. Accordingly, the transfer of a substrate by the traveling device slows down, which causes a problem in which productivity of a semiconductor device manufacturing process using the substrate is reduced.

On the other hand, in the case of the substrate transfer apparatus 1000 according to an embodiment, the second sensors 220 measuring the diameter of the traveling wheel 150 of the traveling device 100 and the third sensor 230 identifying the identification information of the traveling device 100 may move along with a movement of the traveling device 100. Accordingly, when measuring the diameter of the traveling wheel 150, there is no need to reduce the traveling speed of the traveling device 100, and thus, a substrate is smoothly transferred by the traveling device 100, thereby improving the productivity of the semiconductor device manufacturing process.

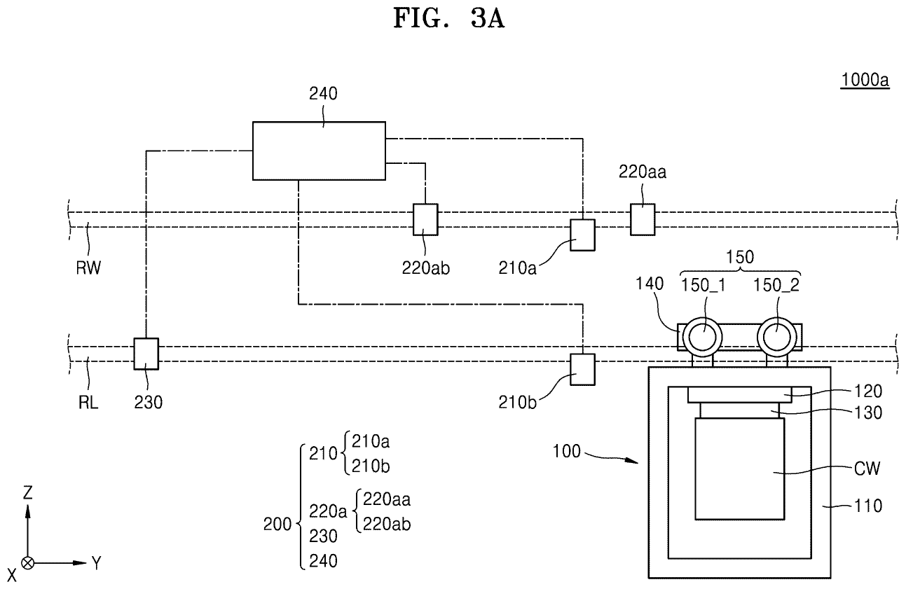

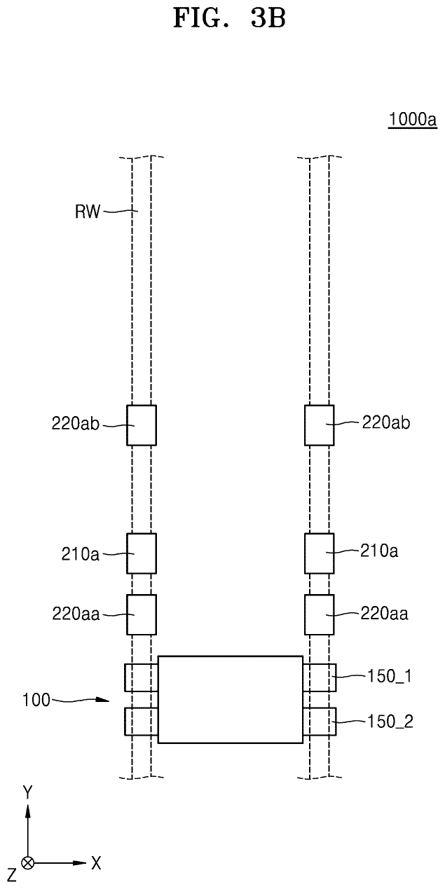

FIG. 3A is a cross-sectional view illustrating a substrate transfer apparatus 1000a according to an embodiment.

FIG. 3B is a plan view illustrating the substrate transfer apparatus 1000a according to an embodiment. Specifically, FIG. 3B is a plan view of the substrate transfer apparatus 1000a in which the traveling rail RL is omitted. Each configuration of the substrate transfer apparatus 1000a shown in FIGS. 3A and 3B is similar to each configuration of the substrate transfer apparatus 1000 described with reference to FIGS. 1 and 2A to 2C, and thus, differences are mainly described below.

Referring to FIGS. 3A and 3B, the substrate transfer apparatus 1000a may include the traveling device 100, the traveling rail RL, the raceway structure RW, and a sensor device 200a.

The sensor device 200a may include the first sensor 210, the second sensor 220, the third sensor 230, and the control device 240.

The first sensor 210 may include the first sub sensor 210a and the second sub sensor 210b. The first sub sensor 210a may be connected to the raceway structure RW, and the second sub sensor 210b may be connected to the traveling rail RL. The first sub sensor 210a and the second sub sensor 210b may be disposed to overlap each other in a vertical direction (i.e., Z direction). In an embodiment, the first sub sensor 210a may be disposed between a second rear sensor 220aa and a second front sensor 220ab in the raceway structure RW. The first sensor 210 may recognize a time when the traveling device 100 enters the traveling rail RL. Specifically, when the traveling device 100 enters the traveling rail RL, a part of the traveling device 100 is aligned with the first sub sensor 210a and the second sub sensor 210b in a vertical direction. Accordingly, a vertical length measured by the first sub sensor 210a and the second sub sensor 210b at the time when the traveling device 100 enters the traveling rail RL may be smaller than the vertical length at the time when the traveling device 100 does not enter the traveling rail RL. Through this, the first sensor 210 may recognize an entry time of the traveling device 100.

The second sensor 220a may include the second rear sensors 220aa and the second front sensors 220ab. The second rear sensors 220aa and the second front sensors 220ab may be connected to the raceway structure RW. Specifically, the two second rear sensors 220aa may be disposed to face each other with respect to a direction (X direction) perpendicular to a traveling direction in the raceway structure RW, and the two second front sensors 220ab may be respectively spaced apart from the second rear sensors 220aa in a Y direction and face each other in the direction (X direction) perpendicular to the traveling direction in the raceway structure RW. In an embodiment, the second sensor 220a may be a sensor capable of measuring a diameter of the traveling wheel 150. Specifically, the second rear sensors 220aa may be sensors measuring a diameter of the rear traveling wheel 150_2, and the second front sensors 220ab may be sensors measuring a diameter of the front traveling wheel 150_1. In an embodiment, each of the second rear sensors 220aa and the second front sensors 220ab may be any one selected from a camera or a displacement sensor such as a laser sensor. For example, the second rear sensors 220aa may be cameras, and the second front sensors 220ab may be displacement sensors. The diameter of the traveling wheel 150 measured by the second sensor 220a may be transmitted to the control device 240. However, the disclosure is not limited thereto, and, for example, when the second sensor 220a is a camera, the second sensor 220a may measure other characteristics of the traveling device 100, for example, whether components of the traveling device 100 are well coupled to each other, through an image obtained by capturing the traveling device 100.

The third sensor 230 may be connected to the traveling rail RL. Specifically, the third sensor 230 may be disposed on only one side of the traveling rail RL. However, the disclosure is not limited thereto, but the two third sensors 230 may be disposed to face each other in the direction (X direction) perpendicular to the traveling direction on the driving rail RL.

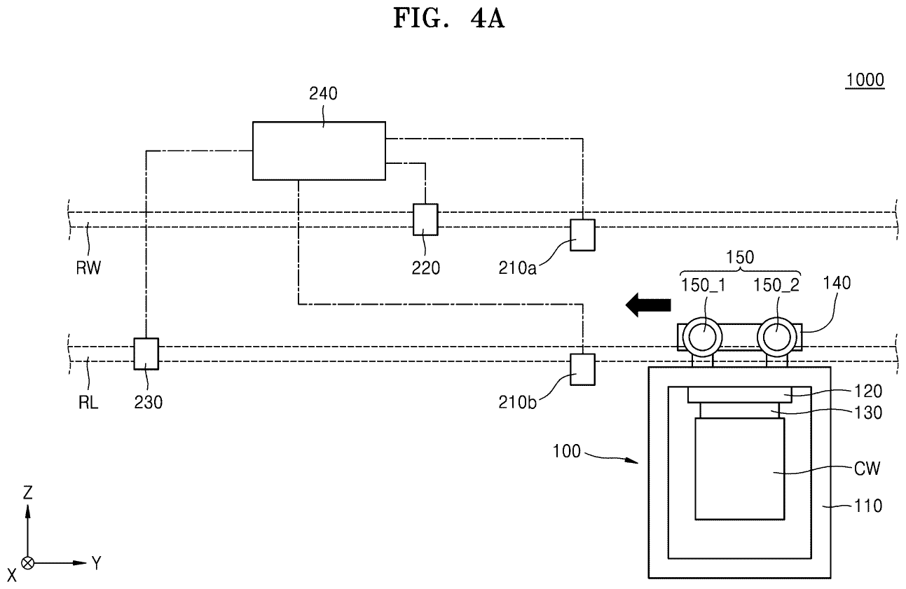

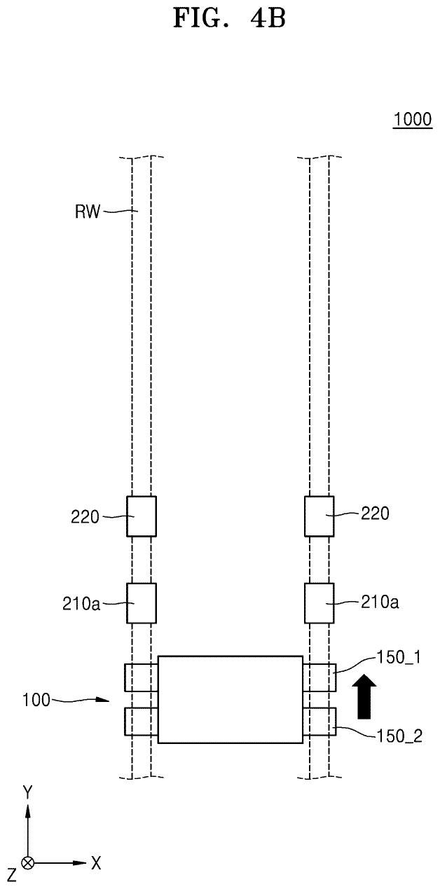

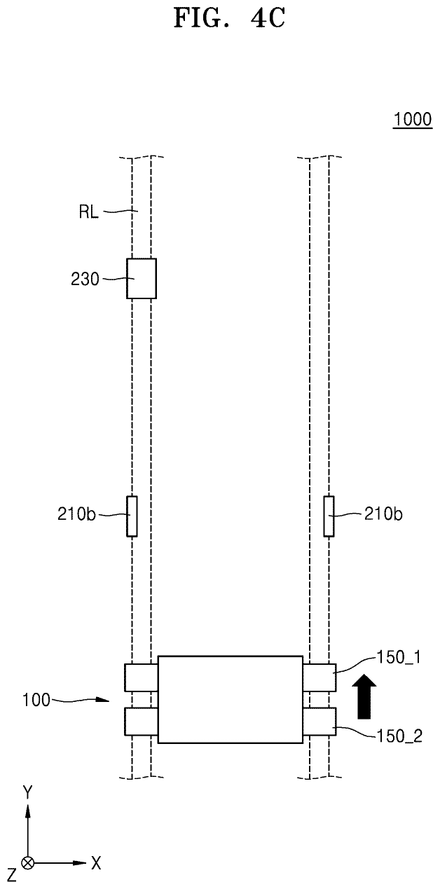

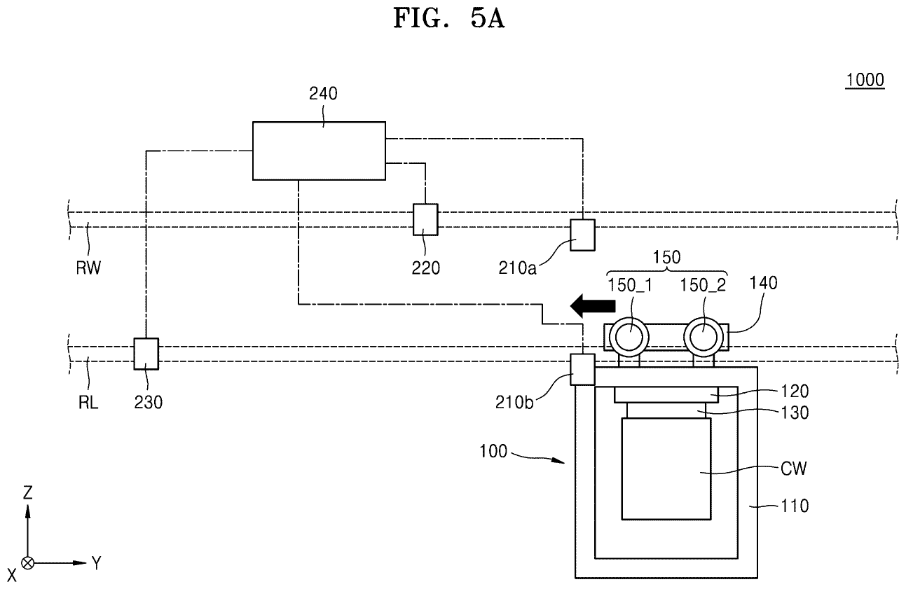

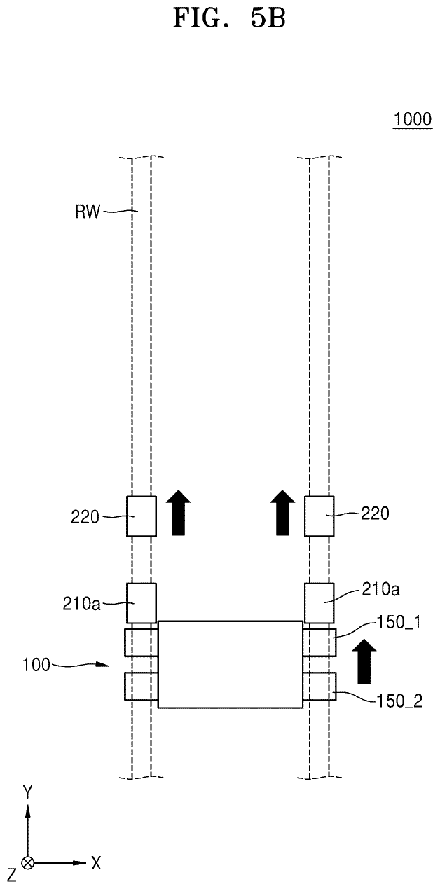

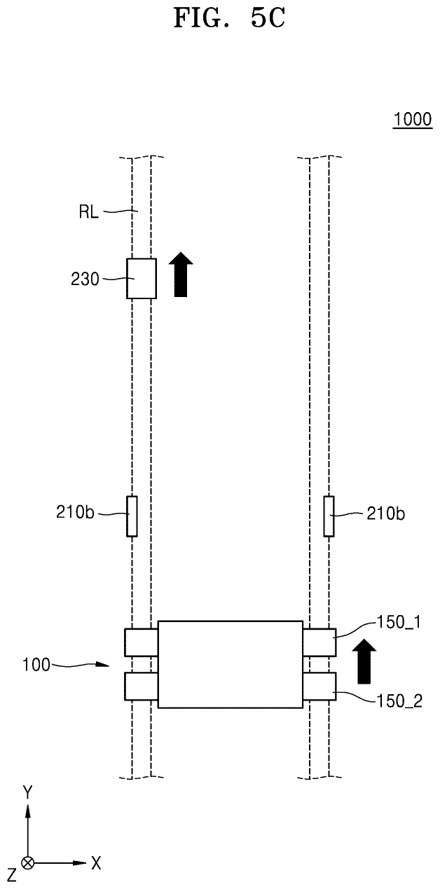

FIGS. 4A to 4C and 5A to 5C are diagrams illustrating an operating method of the substrate transfer apparatus 1000 according to an embodiment. Specifically, FIGS. 4A and 5A are cross-sectional views illustrating the operating method of the substrate transfer apparatus 1000, and FIGS. 4B, 4C, 5B, and 5C are plan views illustrating the operating method of the substrate transfer apparatus 1000.

Referring to FIGS. 4A to 4C, first, the traveling device 100 may travel along the travel direction (Y direction) on the traveling rail RL at a certain traveling speed. As the traveling device 100 travels along the traveling rail RL, the traveling device 100 may gradually approach the first sub sensor 210a and the second sub sensor 210b.

Referring to FIGS. 5A to 5C, the traveling device 100 may travel along the traveling rail RL, and the front traveling wheel 150_1 of the traveling device 100 may overlap with the first sub sensor 210a and the second sub sensor 210b in the vertical direction. Accordingly, a vertical length of an empty space between the raceway structure RW and the traveling rail RL measured by the first sub sensor 210a and the second sub sensor 210b is reduced. Through this, the first sub sensor 210a and the second sub sensor 210b recognize an entry time of the traveling device 100 and transmit the entry time to the control device 240.

Next, the control device 240 may move the second sensor 220 and the third sensor 230 based on information transmitted from the first sub sensor 210a and the second sub sensor 210b. Specifically, the control device 240 may move the second sensor 220 and the third sensor 230 in the same direction as the traveling direction of the traveling device 100 at the same speed as the traveling speed of the traveling device 100. Through this, the second sensor 220 may measure the diameter of the traveling wheel 150 of the traveling device 100 without reducing the traveling speed of the traveling device 100, and the third sensor 230 may identify identification information of the traveling device 100. When the second sensor 220 and the third sensor 230 completely measure the traveling device 100, the control device 240 may stop the second sensor 220 and the third sensor 230 or may return the second sensor 220 and the third sensor 230 to their original positions. The diameter of the traveling wheel 150 measured by the second sensor 220 and the identification information of the traveling device 100 measured by the third sensor 230 may be transmitted to the control device 240, and the control device 240 may transmit the received diameter and identification information as server data.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate transfer apparatus comprising:
a traveling rail comprising a straight section and a curved section;
a raceway structure disposed on the traveling rail and configured to fix the traveling rail
a traveling device comprising a traveling wheel configured to travel on the traveling rail so as to transfer a substrate;
a first sensor connected to the raceway structure and configured to recognize the traveling device;
at least one second sensor connected to the raceway structure and configured to recognize the traveling device; and
a third sensor connected to the traveling rail and configured to recognize the traveling device,
wherein the at least one second sensor and the third sensor are configured to move in a traveling direction of the traveling device.

2. The substrate transfer apparatus of claim 1, wherein the at least one second sensor and the third sensor are configured to move at a same speed as a traveling speed of the traveling device.

3. The substrate transfer apparatus of claim 1, wherein the first sensor is configured to recognize a time when the traveling device enters the traveling rail.

4. The substrate transfer apparatus of claim 1, wherein the at least one second sensor is configured to measure a diameter of the traveling wheel.

5. The substrate transfer apparatus of claim 1, wherein the third sensor is configured to identify identification information about the traveling device.

6. The substrate transfer apparatus of claim 1, wherein, in the traveling direction, the first sensor is disposed relatively adjacent to the traveling device, and the at least one second sensor is disposed relatively far from the traveling device.

7. The substrate transfer apparatus of claim 1, wherein the at least one second sensor includes two second sensors, and the two second sensors are disposed to face each other with respect to a direction perpendicular to the traveling direction in the raceway structure.

8. The substrate transfer apparatus of claim 1, wherein the at least one second sensor is a camera or a displacement sensor, and the third sensor is a camera.

9. The substrate transfer apparatus of claim 1, wherein the at least one second sensor and the third sensor are configured to move at a same time.

10. The substrate transfer apparatus of claim 1, wherein
the third sensor is disposed in the straight section of the traveling rail, and the first sensor and the at least one second sensor are disposed in the raceway structure corresponding to the straight section of the traveling rail.

11. The substrate transfer apparatus of claim 1, further comprising: a control device configured to control operations of the first sensor, the at least one second sensor, and the third sensor.

12. A substrate transfer apparatus comprising:
a traveling rail comprising a straight section and a curved section;
a raceway structure disposed on the traveling rail and configured to fix the traveling rail;
a traveling device comprising a traveling wheel configured to travel on the traveling rail so as to transfer a substrate;
a first sensor connected to the raceway structure and configured to recognize the traveling device;
at least one second front sensor connected to the raceway structure and configured to recognize the traveling device;
at least one second rear sensor connected to the raceway structure to be spaced apart from the at least one second front sensor in a traveling direction of the traveling device and configured to recognize the traveling device; and
a third sensor connected to the traveling rail and configured to recognize the traveling device,
wherein the at least one second front sensor, the at least one second rear sensor, and the third sensor are configured to move in the traveling direction.

13. The substrate transfer apparatus of claim 12, wherein the first sensor is disposed between the at least one second front sensor and the at least one second rear sensor in the traveling direction.

14. The substrate transfer apparatus of claim 12, wherein the at least one second front sensor, the at least one second rear sensor, and the third sensor are configured to move at a same speed as a traveling speed of the traveling device.

15. The substrate transfer apparatus of claim 12, wherein the at least one second front sensor and the at least one second rear sensor are configured to measure a diameter of the traveling wheel.

16. The substrate transfer apparatus of claim 12, wherein the third sensor is configured to identify identification information about the traveling device.

17. The substrate transfer apparatus of claim 12, wherein the at least one second front sensor, the at least one second rear sensor, and the third sensor are configured to move at a same time.

18. The substrate transfer apparatus of claim 12, wherein the third sensor is disposed in the straight section of the traveling rail, and the first sensor, the at least one second front sensor, and the at least one second rear sensor are disposed in the raceway structure corresponding to the straight section of the traveling rail.

19. A substrate transfer method comprising:
recognizing, through a first sensor, a time when a traveling device in which a substrate is accommodated enters a traveling rail;
moving a second sensor and a third sensor in a traveling direction of the traveling device when entry of the traveling device is recognized; and
measuring, by the second sensor, a diameter of a traveling wheel of the traveling device while the second sensor is moving, and identifying, by the third sensor, identification information about the traveling device while the third sensor is moving.

20. The substrate transfer method of claim 19, wherein the second sensor and the third sensor move at a same speed as a traveling speed of the traveling device.
